(19) United States
(12) Patent Application Publication
(10) Pub. No.: US 2017/0317031 A1
(43) Pub. Date: Nov. 2, 2017

(54) Fabrication Method OF A Package Substrate

(71) Applicant: PHOENIX PIONEER TECHNOLOGY CO., LTD., Hsinchu County (TW)

(72) Inventors: CHU-CHIN HU, Hsinchu County (TW); SHIH-PING HSU, Hsinchu County (TW); CHIN-MING LIU, Hsinchu County (TW)

(21) Appl. No.: 15/654,903

(22) Filed: Jul. 20, 2017

Related U.S. Application Data
(62) Division of application No. 15/392,246, filed on Dec. 28, 2016.

(30) Foreign Application Priority Data
Jan. 5, 2016 (TW) 105100173

(51) Int. Cl. H01L 23/538; H01L 23/00; H01L 21/48; H01L 23/31; H01L 21/56

(52) U.S. Cl. CPC H01L 23/5389; H01L 23/5383; H01L 24/16; H01L 23/5386; H01L 23/5384; H01L 21/4853; H01L 23/3114; H01L 21/565; H01L 21/486; H01L 21/4857; H01L 2224/16235

(57) ABSTRACT

This disclosure provides a package substrate and its fabrication method. The package substrate comprises: a first wiring layer including at least one first metal wire; a conductive connecting unit including a first connecting unit and a second connecting unit on the first wiring layer; a circuit chip having at least one connection terminal and disposed on the first connecting unit; a molding compound layer covering the wiring layer, the conductive connecting unit and the circuit chip; and a second wiring layer including at least one second metal wire and connected to the second connecting unit; wherein the first connecting unit is configured for connecting one of the at least one connection terminal with one of the at least one first metal wire.

### CROSS REFERENCE TO RELATED APPLICATION

This application claims the benefit of Taiwan application Serial No. 105100173, filed on Jan. 5, 2016, the disclosure of which is incorporated by reference herein in its entirety.

### FIELD OF THE INVENTION

The present invention relates to a package substrate and its fabrication method.

### BACKGROUND OF THE INVENTION

As recent rapid trend in modern electronic devices is not only toward lighter and smaller devices, but also toward multi-function and high-performance devices, the integrated-circuit (IC) fabrication and technology has to evolve correspondingly toward a more high-density and miniature design so as to allow more electronic components to be received inside limited chip space. Consequently, the relating IC package substrate and the package technology are evolved accordingly to meet the trend.

In the art, a chip or die can be embedded in a package substrate by the so called “embedded component technology”. Such kind of package substrate has the advantages of low noise disturbance and downsized product. Conventionally, a chip or die is first embedded in the molding compound, which is the main body of a package substrate, and circuitry-layout wires of the package substrate are formed after the embedding process. However, for a package device with fine-pitch wires, the fabrication process is comparatively difficult and the chip has to be scrapped along with the package substrate having defects in the formation of the wiring layer. Moreover, an embedded chip has a complicated bonding-out path to the redistribution layer, which may be formed by costly processes like laser engraving. To reduce fabrication cost and improve production yield, it is in need of a new and advanced packaging solution.

### SUMMARY OF THE INVENTION

According to one aspect of the present disclosure, one embodiment provides a package substrate, which comprises: a first wiring layer including at least one first metal wire; a conductive connecting unit including a first connecting unit and a second connecting unit on the first wiring layer; a circuit chip having at least one connection terminal and disposed on the first connecting unit; a molding compound layer covering the wiring layer, the conductive connecting unit and the circuit chip; and a second wiring layer including at least one second metal wire and connected to the second connecting unit; wherein the first connecting unit is configured for connecting one of the at least one connection terminal with one of the at least one first metal wire.

In the embodiment, the first connecting unit includes a metal pillar or a solder bump.

In the embodiment, the package substrate further comprises a metal carrier below the first wiring layer.

According to one aspect of the present disclosure, one embodiment provides a package substrate, which comprises: providing a carrier; forming a first wiring layer on the carrier while enabling the first wiring layer to be formed including at least one first metal wire; forming a conductive connecting unit including a first connecting unit and a second connecting unit on the first wiring layer; providing a circuit chip having at least one connection terminal to be disposed on the first connecting unit while enabling the first connecting unit to connect one of the at least one connection terminal with one of the at least one first metal wire and a space to be formed between the circuit chip and the carrier; forming a molding compound layer on the first wiring layer while enabling the molding compound layer to cover the first wiring layer, the conductive connection unit and the circuit chip.

In the embodiment, the first connecting unit includes a first metal pillar or a solder bump.

In the embodiment, the method further comprises: removing a portion of the molding compound layer so that a top surface of the circuit chip is exposed; and removing the carrier.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 shows a cross-sectional view of a package substrate according to a first embodiment of the present invention.

FIGS. 2 to 8 are cross-sectional views of the package substrate according to the embodiment of FIG. 1 in the present disclosure, corresponding to different process steps.

FIG. 9 is a cross-sectional view of a package substrate according to a second embodiment of the present invention.

FIG. 10 is a cross-sectional view of the package substrate according to a third embodiment in the present disclosure.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

In the following embodiments of the present disclosure, when an element is described to be disposed above/mounted on top of or below/under another element, it comprises either the element is directly or indirectly disposed above/below the other element, i.e. when indirectly, there can be some other element arranged between the two; and when directly, there is no other element disposed between the two. It is noted that the descriptions in the present disclosure relate to “above” or “below” are based upon the related diagrams provided, but are not limited thereby. Moreover, the terms “first”, “second”, and “third”, and so on, are simply used for clearly identifying different elements of the same nature, but those elements are not restricted thereby and must be positioned or arranged accordingly. In addition, the size or thickness of each and every element provided in the following diagrams of the present disclosure is only schematic representation used for illustration and may not represent its actual size.

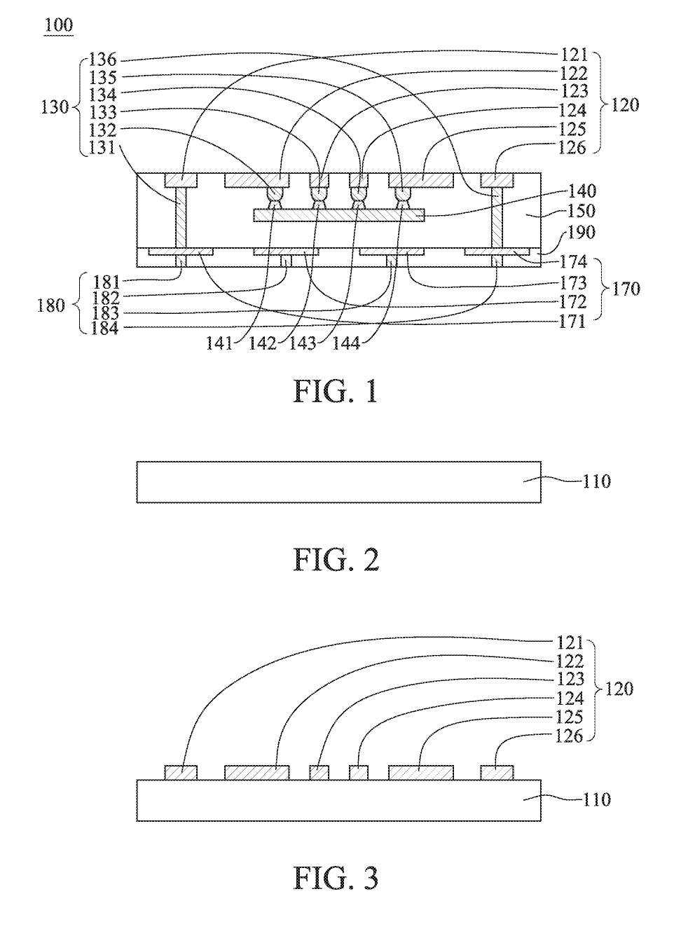

FIG. 1 shows a cross-sectional view of a package substrate 100 according to a first embodiment of the present invention. The package substrate 100 comprises: a first wiring layer 120, a conductive connecting unit 130, a circuit chip 140, a molding compound layer 150, a second wiring layer 170, a conductive pillar layer 180 and a dielectric material layer 190. The first wiring layer 120 is formed with at least one metal wire that is to be used for constructing the predefined upper-layer circuitry layout of the package substrate 100. The second wiring layer 170 is formed with at least one metal wire that is to be used for constructing the predefined lower-layer circuitry layout of the package substrate 100. The conductive connecting unit 130 is formed on the first wiring layer 120. The circuit chip 140 has at least one connection terminal and is disposed on the conductive connecting unit 130. In the embodiment, the first wiring layer 120 includes metal wires 121-126, the conductive connecting unit 130 includes connection units 131-136, the circuit chip 140 is provided with connection terminals 141-144, the second wiring layer 170 includes metal wires 171-174, as shown in FIG. 1. Each of the connection units 132-134 is used to connect one of the connection terminals 141-144 with one of the metal wires 122-125. For example, the connection unit 132 connects the connection terminal 141 to the metal wire 122, the connection unit 133 connects the connection terminal 142 to the metal wire 123, the connection unit 134 connects the connection terminal 143 to the metal wire 124, and the connection unit 135 connects the connection terminal 144 to the metal wire 125. Also, the connection units 131 and 136 are used to connect the first wiring layer 120 and the second wiring layer 170. For example, the connection unit 131 connects the metal wire 171 to the metal wire 121, and the connection unit 136 connects the metal wire 174 to the metal wire 126. Moreover, the molding compound layer 150 covers the first wiring layer 120, the conductive connecting unit 130 and the circuit chip 140, and the second wiring layer 170 is formed on the molding compound layer 150. The conductive pillar layer 180 is formed with at least one metal pillar on the second wiring layer 170. For example, the conductive pillar layer 180 may include metal pillars 181-184 corresponding to the metal wires 171-174. The package substrate 100 can be connected to an external circuit through the conductive pillar layer 180. The dielectric material layer 190 is formed on the molding compound layer 150 while enabling the dielectric material layer 190 to cover the metal wires 171-174 and the metal pillars 181-184, acting as a protective layer at the outermost layer of the package substrate 100.

To form the first wiring layer 120, a metal layer of Cu, Ni, Sn, Ni/Au or their combination is formed on a carrier substrate (not shown) by electrolytic plating, evaporating or sputtering, and then patterned by means of photolithography to form the metal wires 121-126.

The circuit chip 140 may be an active circuit component, which is a die diced from a semiconductor wafer following the IC fabrication process. In the embodiment, the die is provided with connection terminals 141-144 in the form of pin, pad or solder bump, and is embedded in the package substrate 100. Thereby, for the electronic product based on the package substrate 100, it may have a smaller product size, be less affected by the noise-induced disturbance and thus be applicable to design and fabrication of application processor (AP) or power management chips for a mobile device. As shown in FIG. 1, the connection terminals 141-144 can be correspondingly positioned at the connection units 132-135 when the circuit chip 140 is disposed on the conductive connecting unit 130, without use of any sophisticated alignment technique.

In order to bond the circuit chip 140 to the first wiring layer 120 without use of any sophisticated alignment technique, the connection units 132-135 in the form of pillar (e.g. copper pillar) or bump (e.g. solder bump) are formed on the first wiring layer 120, so that the connection terminals 141-144 are correspondingly positioned at the connection units 131-134 when the circuit chip 140 is disposed at a pre-determined position of the conductive connecting unit 130. Thus, the wafer-level fabrication cost of the package substrate can be effectively reduced. In the embodiment, each of the connection units 132-135 is used to connect one of the connection terminals 141-144 with one of the metal wires 122-125. For example, the connection unit 132 connects the connection terminal 141 to the metal wire 122, the connection unit 133 connects the connection terminal 142 to the metal wire 123, the connection unit 134 connects the connection terminal 143 to the metal wire 124, and the connection unit 135 connects the connection terminal 144 to the metal wire 125, as shown in FIG. 1. In the above-recited way, the circuit chip 140 is electrically connected to the first wiring layer 120 according to circuitry design of the package substrate 100. In the embodiment, the connection units 131 and 136 in a pillar structure are also formed on the first wiring layer 120, so as to connect the first wiring layer 120 and the second wiring layer 170. For example, the connection unit 131 connects the metal wire 171 to the metal wire 121, and the connection unit 136 connects the metal wire 174 to the metal wire 126.

The molding compound layer 150 can be formed of a dielectric material selected from the group consisting of novolac-based resin, epoxy-based resin and silicon-based resin by a molding means like compression molding. The molding compound layer 150 covers the circuit chip 140 and fills up the space between the circuit chip 140 and the first wiring layer 120, so that the package substrate 100 can have a firm structure to build up an electronic device or product. Moreover, the part of the molding compound layer 150 over the top surface of the circuit chip 140 may act as a protective layer to protect the circuit chip 140 from any adverse affect of its surrounding environment or posterior processes such as soldering.

In the embodiment, the package substrate 100 can be a flip-chip chip size package (FCCSP) substrate used to construct the so-called “molded interconnection substrate (MIS)”. Also, the package substrate 100 may have a circuitry layout with a stacked structure of multiple wiring layers; for example, a package substrate with two, three or more wiring layers. In another embodiment, a heat sink, an IC chip or die, or another package substrate can be disposed on the package substrate 100 to form a 3D-stacking system such as the package-on-package (PoP) structure.

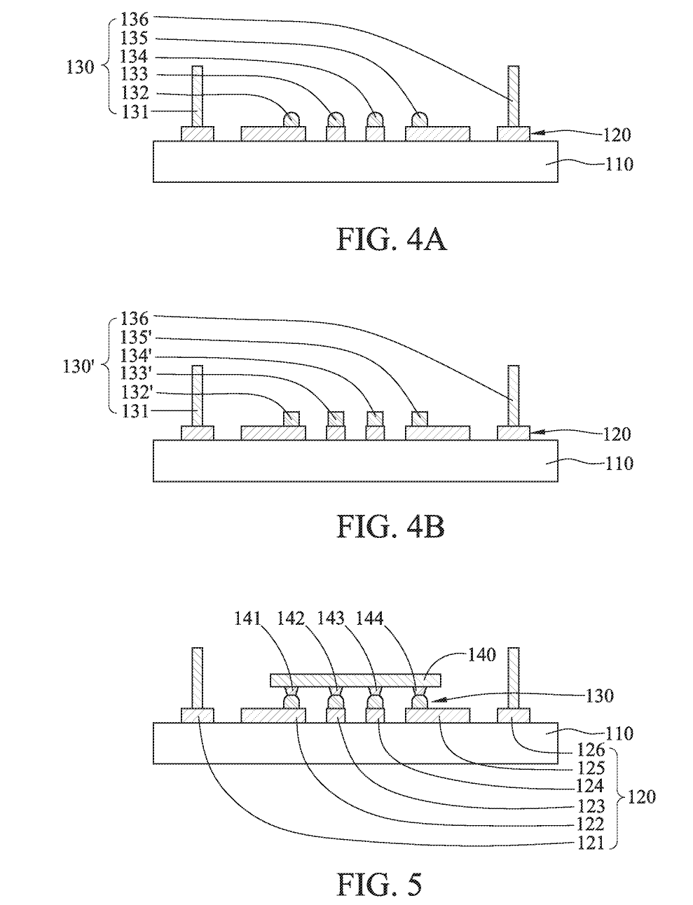

The fabrication process will be described in detail in the following paragraphs. Wherein, FIG. 2-8 are cross-sectional views of the package substrate 100 according to the embodiment of FIG. 1 in the present disclosure, corresponding to different process steps.

As shown in FIG. 2, a carrier 110 is provided to carry and support electronic components and conductive wires of the package substrate 100, e.g. the first wiring layer 120, the conductive connecting unit 130, the circuit chip 140, and the protection molding compound layer 150 in FIG. 1. The carrier 110 can be a metal substrate plate or a dielectric substrate plate coated with a metal layer, in which the metal can be Fe, Cu, Ni, Sn, Al, Ni/Au or their combination.

Next, a first wiring layer 120 is formed on the carrier 110 while enabling the first wiring layer 120 to be formed including at least one first metal wire, to be lower-layer wiring of the package substrate 100, as shown in FIG. 3. For example, a photoresist layer can be deposited on the carrier 110 by laminating or spin-coating, and then patterned by exposure to light and developing. By electrolytic plating, a metal layer can be deposited on the carrier 110 except the region covered by the patterned photoresist layer; thus, the metal wires 121-126 are formed on the carrier 110. Alternatively, the first wiring layer 120 can be formed by laser engraving. For example, a dielectric layer can be deposited on the carrier 110 and then patterned by laser engraving. By evaporating or sputtering, a metal layer can be deposited on the carrier 110 and the patterned dielectric layer. By using the lift-off processing, the patterned dielectric layer can be washed out together with the part of the metal layer directly on its top surface, and the remainder of the metal layer not on the patterned dielectric layer stays on the carrier 110 to be the metal wires 121-126 in the first wiring layer 120. In the embodiment, the first wiring layer 120 includes metal wires 121-126 made of Cu, Ni, Sn, Ni/Au or their combination.

Next, a conductive connecting unit 130 including connection units 131-134 is formed on the first wiring layer 120. As shown in FIG. 4A, the connection units 132-135 are solder bumps configured for bonding an IC chip or die to the first wiring layer 120, and the connection units 131 and 136 in a pillar structure are also formed on the first wiring layer 120, so as to connect the first wiring layer 120 and the second wiring layer 170 in the subsequent fabrication steps. The quantity of the connection units 131-136 depends on the circuitry layout of the package substrate 100. In another embodiment, the connection units 131, 132′-135′ and 136 are in the form of pillar made of Cu, Al, Ni, Sn, or their combination, and the connection units 131 and 136 are longer than the connection units 132′-135′ as shown in FIG. 4B. In the following paragraphs, the package substrate 100 is fabricated based on the solder bumps 132-135 as shown in FIG. 4A, but the process is also applicable to the metal pillars 132′-135′ as shown in FIG. 4B.

Next, a circuit chip 140 having connection terminals 141-144 is disposed on the conductive connecting unit 130 while enabling each of the connection units 132-135 to connect one of the connection terminals 141-144 with one of the metal wires 122-125. The circuit chip 140 may be an active circuit component, which is a die diced from a semiconductor wafer following the IC fabrication process. In the embodiment, the die is provided with connection terminals 141-144 in the form of pin, pad or solder bump, and is embedded in the package substrate 100. As shown in FIG. 5, the connection terminals 141-144 can be correspondingly positioned at the connection units 132-135 when the circuit chip 140 is disposed on the conductive connecting unit 130, without use of any sophisticated alignment technique. That is to say, the connection unit 132 connects the connection pin 141 to the metal wire 122, the connection unit 133 connects the connection pin 142 to the metal wire 123, the connection unit 134 connects the connection pin 143 to the metal wire 124, and the connection unit 135 connects the connection pin 144 to the metal wire 125, so that the circuit chip 140 can be connected to the first wiring layer 120 according to circuitry design of the package substrate 100.

Next, a molding compound layer 150 is formed on the first wiring layer 120 while enabling the molding compound layer 150 to cover the conductive connecting unit 130 and the circuit chip 140 and fill up the space between the circuit chip 140 and the carrier 110, as shown in FIG. 6. The molding compound layer 150 can be formed of a dielectric material selected from the group consisting of novolac-based resin, epoxy-based resin and silicon-based resin by a molding means like compression molding. The molding compound layer 150 covers the circuit chip 140 and the connection units 131 and 136 and fills up the space between the circuit chip 140 and the first wiring layer 120, so that the package substrate 100 can have a firm structure to build up an electronic device or product. Moreover, the part of the molding compound layer 150 over the top surface of the circuit chip 140 may act as a protective layer to protect the circuit chip 140 from any adverse affect of its surrounding environment or posterior processes such as soldering.

Next, a second wiring layer 170 is formed with metal wires 171-174 on the molding compound layer 150 as shown in FIG. 7, where the metal wire 171 is bonded to the connection unit 131 and the metal wire 174 is bonded to the connection unit 136. The formation and composition of the second wiring layer 170 are similar to those of the first wiring layer 120 and are not described redundantly here. Then, a conductive pillar layer 180 is formed with metal pillars 181-184 on the second wiring layer 170. For example, the metal pillars 181-184 are bonded to the metal wires 171-174, respectively.

Next, a dielectric material layer 190 is formed on the molding compound layer 150 while enabling the dielectric material layer 190 to cover the metal wires 171-174 and the metal pillars 181-184 as shown in FIG. 8. The formation and composition of the dielectric material layer 190 are similar to those of the molding compound layer 150 and are not described redundantly here. The package substrate 100 can be connected to an external circuit through the conductive pillar layer 180, and the dielectric material layer 190 may act as a protective layer to protect the package substrate 100 from any adverse affect of its surrounding environment or posterior processes. The package substrate 100 of FIG. 1 can be obtained after removal of the carrier 110.

In the art, a chip or die can be embedded in a package substrate by the embedded component technology. Such kind of package substrate has the advantages of low noise disturbance and downsized product. Taking the package substrate 100 of FIG. 1 as an example, the circuit chip 140 is first embedded in the molding compound layer 150 (main body of the package substrate 100), and the first wiring layer 120 (circuitry-layout wires or redistribution layer of the package substrate 100) is formed after the embedding process in the prior-art embedded component technology. However, for a package device with fine-pitch wires in the first wiring layer 120, the fabrication process is comparatively difficult and the circuit chip 140 has to be scrapped along with the package substrate having defects caused in the formation of the first wiring layer 120. Moreover, an embedded chip has a complicated bonding-out path to the redistribution layer, which may be formed by costly processes like laser engraving.

In contrast to the prior-art embedded component technology, the first wiring layer 120 (circuitry-layout wires or redistribution layer of the package substrate 100) is formed before the circuit chip 140 is embedded in the package substrate 100. After that, the circuit chip 140 is attached to the first wiring layer 120, and then the molding compound layer 150 is formed by molding to complete the package substrate 100 of FIG. 1. The first wiring layer 120 with fine-pitch wires is formed before the disposition of the circuit chip 140 and the bonding-out path of the circuit chip 140 can be included in the first wiring layer 120 without any extra process, so the fabrication cost can be reduced and the production yield can be improved.

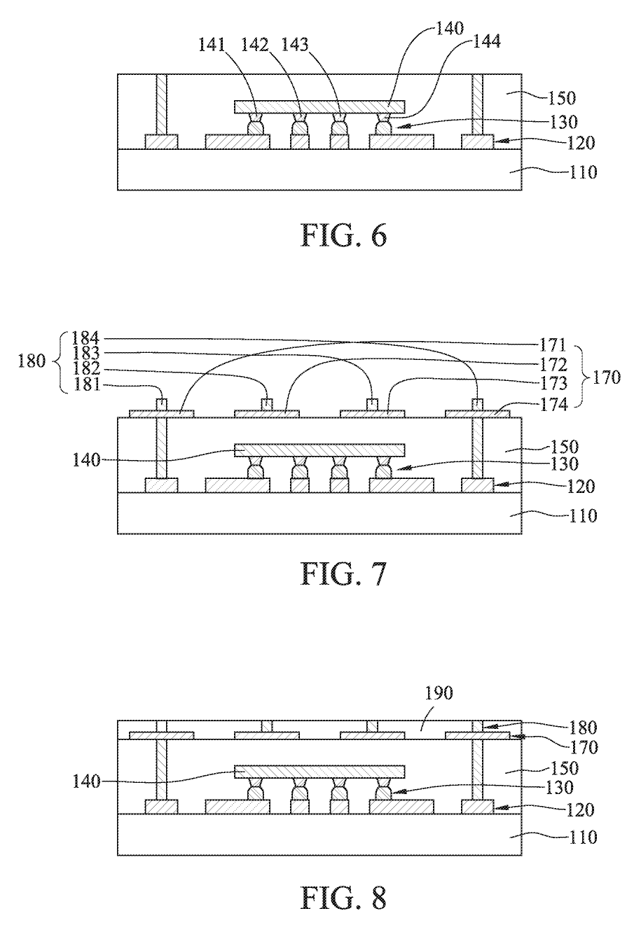

FIG. 9 shows a cross-sectional view of a package substrate 200 according to a second embodiment of the present invention. The upper part of the molding compound layer 150 of the package substrate in FIG. 6 can be removed to expose top surfaces of the circuit chip 140. For example, the molding compound layer 150 is polished to remove its upper part downwards until the top surface of the circuit chip 140 is exposed. The exposure of the top surface may facilitate heat dissipation of the circuit chip 140.

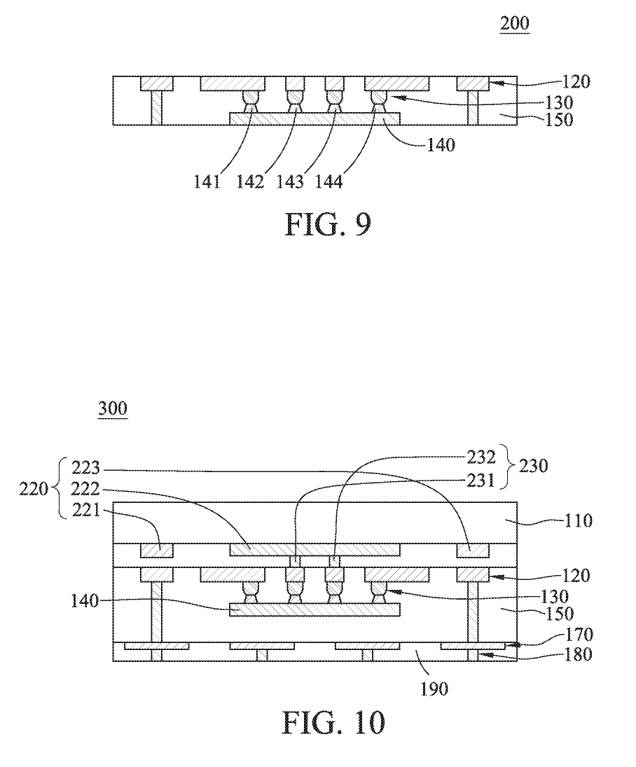

As above-recited, the carrier 110 is a conductive substrate plate because it is a metal plate or a dielectric plate coated with metal layer. So, it can be reserved in the process after FIG. 6 as a heat sink to dissipate the heat in the circuit chip 140. Here, the first wiring layer 120 may act as a heat-dissipation path to conduct the heat generated in the circuit chip 140 to the carrier 110. In such a case, a circuitry layout can be additionally formed on the molding compound layer 150. For example, FIG. 10 is a cross-sectional view of the package substrate 300 according to a third embodiment in the present disclosure. The package substrate 300 can be regarded as an extension to the package substrate 100 of FIG. 1. As compared with the package substrate in FIG. 8, the package substrate 300 further comprises a third wiring layer 220 and a conductive pillar layer 230 interposed between the carrier 110 and the first wiring layer 120. The third wiring layer 220 may include metal wires 221-223, and the conductive pillar layer 230 may include metal pillars 231 and 232 connected to the metal wire 222. Thus, the first wiring layer 120 can offer to conduct both heat and electricity from the circuit chip 140. In the embodiment, the metal wires 123 and 124, the metal pillars 231 and 232 and the metal wire 222 are combined to be a heat-dissipation path to conduct the heat generated in the circuit chip 140 to the carrier 110, which serves as a heat sink. Also, the metal wires 121, 122, 125 and 126 and the metal pillars 131 and 136 are combined to be a signal-propagation path to conduct the electrical signals generated in the circuit chip 140 to the second wiring layer 170, to be connected to an external circuit.

Moreover, various package structures can be developed based on the package substrate 100 in FIG. 1. For example, solder balls may be formed below the package substrate 100 to connect it with an external circuit, surface-mount-technology (SMT) devices or other circuit chips can be mounted on the package substrate 100, and other package substrates can be stacked on or below the package substrate 100 to form a package-on-package (PoP) product.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A method for fabricating a package substrate, comprising steps of:
(A) providing a carrier;
(B) forming a first wiring layer on the carrier while enabling the first wiring layer to be formed including at least one first metal wire;
(C) forming a conductive connecting unit including a first connecting unit and a second connecting unit on the first wiring layer;
(D) providing a circuit chip having at least one connection terminal to be disposed on the first connecting unit while enabling the first connecting unit to connect one of the at least one connection terminal with one of the at least one first metal wire and a space to be formed between the circuit chip and the carrier;
(E) forming a molding compound layer on the first wiring layer while enabling the molding compound layer to cover the first wiring layer, the conductive connection unit and the circuit chip.

2. The method of claim 1, wherein the first connecting unit includes a metal pillar.

3. The method of claim 1, wherein the first connecting unit includes a solder bump.

4. The method of claim 1, further comprising:
(F1) removing a portion of the molding compound layer so that a top surface of the circuit chip is exposed; and
(F2) removing the carrier.
